(19) United States
(12) Patent Application Publication
(10) Pub. No.: US 2026/0350277 A1
(43) Pub. Date: Nov. 5, 2026

(54) METHODS OF RELATIVE PERMEABILITY ESTIMATIONS FROM NMR MEASUREMENT OF FORMATIONS

(71) Applicant: Schlumberger Technology Corporation, Sugar Land, TX (US)

(72) Inventors: Chang-Yu Hou, Cambridge, MA (US); Saad Omar, Cambridge, MA (US); Lalitha Venkataramanan, Cambridge, MA (US)

(21) Appl. No.: 19/661,861

(22) Filed: Apr. 29, 2026

Related U.S. Application Data
(60) Provisional application No. 63/796,666, filed on Apr. 29, 2025.

(51) Int. Cl. G06F 30/28

(52) U.S. Cl. CPC G06F 30/28

(57) ABSTRACT

Techniques include receiving inputs including input data measured in a formation and auxiliary input data corresponding to lab/field data, defining model parameters, generating a fully water saturated surface transverse (T₂) distribution utilizing the inputs and model parameters to realize a pore size distribution of the formation, minimizing a difference between a modeled T₂ and a measured T₂ relaxation response of a partially saturated formation to obtain a wettability characteristic index of the formation, constructing raw relative permeabilities for a pure water-wet and a pure oil-wet formation scenario utilizing the pore size distribution of the formation as two end scenarios, obtaining a relative permeability estimation utilizing the raw relative permeabilities and the wettability characteristic index of the formation to account for influence of wettability changes to the formation by performing interpolation between the two end scenarios, and providing relative permeability estimation to a reservoir simulation model to characterize the formation.

### CROSS-REFERENCE TO RELATED APPLICATIONS

This application is a Non-Provisional application claiming priority to U.S. Provisional Patent Application No. 63/796,666, entitled “RELATIVE PERMEABILITY ESTIMATIONS FROM NMR MEASUREMENT OF PARTIALLY SATURATED WATER-WET, MIXED-WET AND OIL-WET FORMATIONS”, filed Apr. 29, 2025, which is herein incorporated by reference.

### BACKGROUND

The subject matter disclosed herein relates to systems and methods to increase efficiencies in generation of formation estimations via well logging tools.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Producing hydrocarbons from a wellbore drilled into a geological region is a remarkably complex endeavor. In many cases, decisions involved in hydrocarbon exploration and production may be informed by measurements from downhole well-logging tools that are conveyed deep into the wellbore. The measurements may be used to infer properties or characteristics of the geological region surrounding the wellbore.

Well logging tools, such as downhole tools, are utilized to measure well properties for well evaluation. The logging tools can be utilized in conjunction with logging-while-drilling (LWD) operations or mapping-while-drilling operations in which formation evaluation measurements are taken during drilling operations. The measurements made by the logging tools can be useful in providing, for example, bed boundary detection as well as delineation of reservoir boundaries and fluid contacts in a formation. More specifically, nuclear magnetic resonance (NMR) tools may be used to collect such measurements. The measurements from the NMR tool (e.g., T₁ and T₂ distributions) may be indicative of the presence and characteristics (e.g., fluid distribution, fluid quantity, viscosity, porosity, relative permeability, and the like) of a geological formation. However, generation of these results based upon the measurements made by the logging tools has become increasingly complex.

### BRIEF DESCRIPTION OF THE DRAWINGS

Various aspects of this disclosure may be better understood upon reading the following detailed description and upon reference to the drawings in which:

FIG. 1 depicts an example wellsite system for measuring borehole data using various downhole tools and surface tools, in accordance with embodiments of the present disclosure;

FIG. 2 depicts a well control system and logging tool that operate in conjunction with the wellsite system of FIG. 1 to perform natural resource operations, in accordance with embodiments of the present disclosure;

FIG. 3 depicts a nuclear magnetic resonance (NMR) downhole logging tool, in accordance with embodiments of the present disclosure;

FIG. 4 depicts a method of utilizing the NMR downhole logging tool of FIG. 3 to determine relative permeability of a geological formation, in accordance with embodiments of the present disclosure;

FIG. 5 depicts a graphical example of the relative permeability measured for a geological formation, in accordance with embodiments of the present disclosure.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In certain embodiments, a method, includes receiving one or more inputs, wherein the one or more inputs comprise input data measured in situ in a wellbore of a formation and auxiliary input data generated as lab data or based upon field data, defining a characteristic time (T_{c}) and an exponent value (a) that controls a sharpness of a transition from first sized pores of the formation to second sized pores of the formation as model parameters, generating a fully water saturated surface transverse (T₂) distribution utilizing the one or more inputs and the model parameters to realize a pore size distribution of the formation, minimizing a difference between a modeled T₂ relaxation response of a partially saturated formation and a measured T₂ relaxation response of the partially saturated formation to obtain a wettability characteristic index of the formation, constructing raw relative permeabilities for a pure water-wet formation scenario and a pure oil-wet formation scenario utilizing the pore size distribution of the formation as two end scenarios, obtaining a relative permeability estimation utilizing the raw relative permeabilities and the wettability characteristic index of the formation to account for influence of wettability changes to the formation by performing interpolation between the two end scenarios, and providing relative permeability estimation to a reservoir simulation model to characterize the formation.

In certain embodiments, a system includes a nuclear magnetic resonance (NMR)-based logging tool configured to collect measured data in situ in a wellbore of a formation, and a data processing system in communication with the NMR-based logging tool, wherein the data processing system is configured to perform operations including receiving one or more inputs, wherein the one or more inputs include one or more NMR transverse (T₂) relaxation signals as a first portion of the measured data as partially saturated signals in a time domain \tilde{M}(t) or in a T₂ domain \tilde{F}ₚ(T₂), a water saturation (S_{w}) value as a second portion of the measured data, a bulk oil/hydrocarbon T₂ relaxation time distribution, G(T_{2,b,o}), as a third portion of the measured data, and a bulk water/brine T₂ relaxation time (T_{2,b,w}) as the auxiliary input data generated as lab data or based upon field data, defining a characteristic time (T_{c}) and an exponent value (α) that controls a sharpness of a transition from first sized pores from first sized pores of the formation to second sized pores of the formation as model parameters, generating a fully water saturated transverse (T₂) distribution utilizing the one or more inputs and the model parameters to realize a pore size distribution of the formation, minimizing a difference between a modeled T₂ relaxation response of a partially saturated formation and a measured T₂ relaxation response of the partially saturated formation to obtain a wettability characteristic index of the formation, constructing raw relative permeabilities for a pure water-wet formation scenario and a pure oil-wet formation scenario utilizing the pore size distribution of the formation as two end scenarios, obtaining a relative permeability estimation utilizing the raw relative permeabilities and the wettability characteristic index of the formation to account for influence of wettability changes to the formation by performing interpolation between the two end scenarios, and providing relative permeability estimation to a reservoir simulation model to characterize the formation.

In certain embodiments, a tangible, non-transitory, computer-readable medium comprising executable instructions that, when executed by processing circuitry, cause the processing circuitry to perform operations including receiving one or more inputs, wherein the one or more inputs include one or more nuclear magnetic resonance (NMR)-based logging tool measurement as measured data in situ in a wellbore of a formation, wherein the measured data comprises transverse (T₂) relaxation signals as a first portion of the measured data as partially saturated signals in a time domain \tilde{M}(t) or in a T₂ domain \tilde{F}ₚ(T₂), a water saturation (S_{w}) value as a second portion of the measured data, a bulk oil/hydrocarbon T₂ relaxation time distribution, G(T_{2,b,o}), as a third portion of the measured data, and a bulk water/brine T₂ relaxation time (T_{2,b,w}) as auxiliary input data generated as lab data or based upon field data, defining a characteristic time (T_{c}) and an exponent value (α) that controls a sharpness of a transition from first sized pores of the formation to second sized pores of the formation as model parameters, generating a fully water saturated transverse (T₂) distribution utilizing the one or more inputs and the model parameters to realize a pore size distribution of the formation, minimizing a difference between a modeled T₂ relaxation response of a partially saturated formation and a measured T₂ relaxation response of the partially saturated formation to obtain a wettability characteristic index of the formation, constructing raw relative permeabilities for a pure water-wet formation scenario and a pure oil-wet formation scenario utilizing the pore size distribution of the formation as two end scenarios, obtaining a relative permeability estimation utilizing the raw relative permeabilities and the wettability characteristic index of the formation to account for influence of wettability changes to the formation by performing interpolation between the two end scenarios, and providing relative permeability estimation to a reservoir simulation model to characterize the formation.

The brief summary presented above is intended only to familiarize the reader with certain aspects and context of embodiments of the present disclosure without limitation to the claimed subject matter.

### DETAILED DESCRIPTION OF SPECIFIC EMBODIMENTS

Certain embodiments commensurate in scope with the present disclosure are summarized below. These embodiments are not intended to limit the scope of the disclosure, but rather these embodiments are intended only to provide a brief summary of certain disclosed embodiments. Indeed, the present disclosure may encompass a variety of forms that may be similar to or different from the embodiments set forth below.

As used herein, the term “coupled” or “coupled to” may indicate establishing either a direct or indirect connection (e.g., where the connection may not include or include intermediate or intervening components between those coupled), and is not limited to either unless expressly referenced as such. The term “set” may refer to one or more items. Wherever possible, like or identical reference numerals are used in the figures to identify common or the same elements. The figures are not necessarily to scale and certain features and certain views of the figures may be shown exaggerated in scale for purposes of clarification.

As used herein, the terms “inner” and “outer”; “up” and “down”; “upper” and “lower”; “upward” and “downward”; “above” and “below”; “inward” and “outward”; and other like terms as used herein refer to relative positions to one another and are not intended to denote a particular direction or spatial orientation. The terms “couple,” “coupled,” “connect,” “connection,” “connected,” “in connection with,” and “connecting” refer to “in direct connection with” or “in connection with via one or more intermediate elements or members.”

Furthermore, when introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment,” “an embodiment,” or “some embodiments” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase A “or” B is intended to mean A, B, or both A and B.

When generating a simulated model of a geological region, the geological region's relative permeability may describe how multiple fluids flow through the geological region. The relative permeability of a formation may be influenced by the pore size (e.g., the size of openings in porous rock or other media in the formation in which fluids inhabit) or throat distribution (e.g., openings connecting pores) and wettability (e.g., a preference, tendency, or affinity of a solid surface to be in contact with one fluid, such as water, rather than another fluid, such as oil) within the geological region. As such, when estimating relative permeability in a geological region, good control on the relative spreading of the pore size or throat distribution is important. In addition, wettability affects the wetting phase on the pore surface and thus the flow paths through the pore space for two liquids. Estimating relative permeability may include inferring the pore size or throat distribution and the wettability from the logging measurements of a logging tool (e.g., a nuclear magnetic resonance (NMR) tool). That is, a NMR relaxation response in a partially saturated porous medium (e.g., an oil/brine saturated rock formation) may be sensitive to pore size distribution, fluid distribution, wettability, and the like. In turn, the NMR relaxation response, with inputs from other petrophysical interpretations or surface measurements, may enable the extraction of the pore size distribution and wettability properties.

In the present embodiment, the extraction of the geological region's pore size or throat distribution and wettability properties may be calculated by first postulating a fluid distribution as a function of pore size (e.g., the NMR transverse (T₂) relaxation time) for partially saturated formations. The pore size or throat distribution and the fully water-saturated NMR T₂ distribution may be assumed to be correlated (e.g., perfectly correlated). In some techniques, the distribution of a geological region may be translated to another geological region. In addition, a mixed-wet formation, where large pores (e.g., approximately 10 μm, 20 μm, 30 μm or greater) become more oil-wet while smaller pores (e.g., approximately 1 μm, 0.5 μm, 0.1 μm or lesser) remain as water-wet may be a common scenario. Thus, the effect of wettability changes and the fraction of preferred wetting fluid on pore surface may be characterized by a function with respect to the pore size. As such, a functional form may be designed to capture the variance or spreading of the pore size distribution, which can be used to extract the pore size distribution. The use of functional forms to represent different physical processes may enable a more stable inference of the pore size distribution and the wettability characteristics because they are extracted by adjusting any unknown parameters to match modeled partially saturated NMR T₂ signals to measured ones either in a time domain, in a compressed data domain via a singular value decomposition, in a T₂ distribution domain, and the like.

After extracting the pore size distribution and the wettability from the NMR T₂ distribution, further estimations of the formation relative permeability behaviors may be performed. That is, the wettability characteristic function with respect to the pore size may enable the estimation, or constraint, of the relative permeability for mixed-wet geological formations. In some embodiments, a pathway to determine relative permeability may be to first construction the relative permeability behaviors by assuming two anchoring end, water-wet and oil-wet, points. Based on the wettability characteristic function, phenomenologically interpolation between two end points can be performed to estimate the relative permeability of mixed-wet formations.

Accordingly, in some embodiments, NMR measured data can be combined or otherwise supplemented with lab generated data (e.g., synthetic data) and/or field data (e.g., data collected in similar formations to the one being measured), herein referred to as auxiliary input data, to generate a indication of relative permeability of the formation. The techniques may include using a partially saturated NMR signal to reconstruct a fully water saturated NMR signal to generate a pore size distribution and infer a wettability characteristic index (e.g., the wetting properties of the surface of a rock matrix the formation as an indication the a preference, tendency, or affinity of a the rock matrix of the formation to be in contact with one fluid, such as water, rather than another fluid, such as oil) to generate relative permeabilities associated with different wettability. Techniques described herein utilize NMR data as well as auxiliary input data to relative permeability with wettability for a formation, which may be useful as an input to a reservoir simulation model used in planning a hydrocarbon production operation (e.g., to determine a hydrocarbon production schedule, to produce hydrocarbons from the well without damaging the reservoir, and the like).

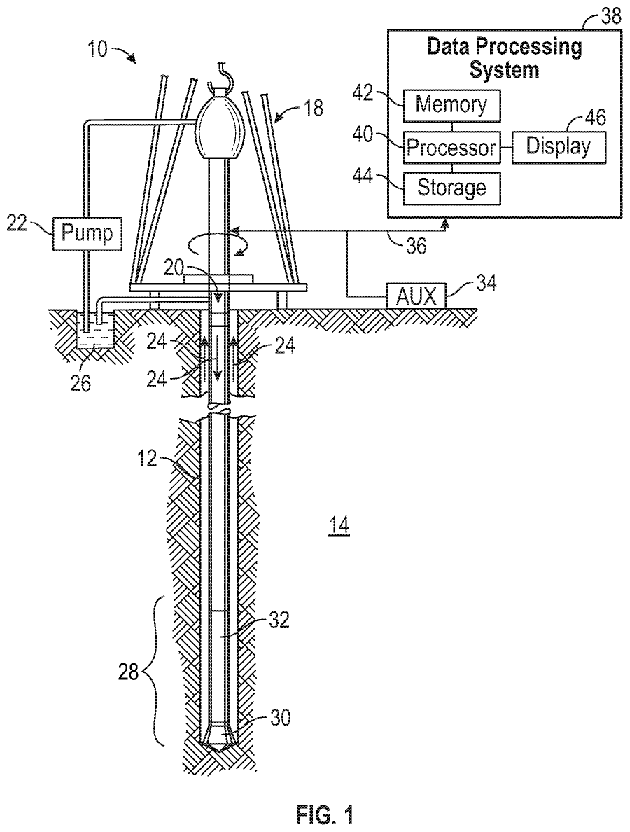

With the foregoing in mind, FIG. 1 illustrates a drilling system 10 that may employ the systems and methods of this disclosure. The drilling system 10 may be used to drill a borehole 12 into a geological region 14. In the drilling system 10, a drilling rig 18 may rotate a drill string 20 within the borehole 12. As the drill string 20 is rotated, a drilling fluid pump 22 may be used to pump drilling fluid, which may be referred to as “mud” or “drilling mud,” downward through the center of the drill string 20, and back up around the drill string 20, as shown by reference arrows 24. At the surface, return drilling fluid may be filtered and conveyed back to a mud pit 26 for reuse. The drilling fluid may travel down to the bottom of the drill string 20 known as the bottom-hole assembly (BHA) 28. The drilling fluid may be used to rotate, cool, and/or lubricate a drill bit 30 that may be a part of the BHA 28. The fluid may exit the drill string 20 through the drill bit 30 and carry drill cuttings away from the bottom of the borehole 12 back to the surface.

The BHA 28 may include the drill bit 30 along with various downhole tools, such as one or more logging tools 32. The BHA 28 may thus convey the one or more logging tools 32 through the geological region 14 via the borehole 12. As described in greater detail herein, the one or more logging tools 32 may be any suitable downhole tool that emits electromagnetic waves within the borehole 12 (e.g., a downhole environment). The downhole tools, which may include the one or more logging tools 32, may collect a variety of information relating to the geological region 14 and the state of drilling in the borehole 12. For instance, the downhole tools may be nuclear magnetic resonance (NMR) logging tools. The downhole tools, which may include the one or more logging tools 32, may collect a variety of information relating to the geological region 14, such as fluid-filled porosity, relative permeability, pore size, wettability, and the like. Likewise, the downhole tools may be measurement-while-drilling (MWD) tools that measure certain drilling parameters, such as the temperature, pressure, orientation of the drill bit 30, mapping-while-drilling tools, and so forth. Although FIG. 1 illustrates the one or more logging tools 32 included in the BHA 28 with drill bit 30, the one or more logging tools 32 may be conveyed through the geological region 14 via the borehole 12 subsequent to drilling operations.

The one or more logging tools 32 may receive energy from an electrical energy device or an electrical energy storage device, such as an auxiliary power source 34 or another electrical energy source to power the tool. In some embodiments, the one or more logging tools 32 may include a power source within the one or more logging tools 32, such as a battery system or a capacitor, to store sufficient electrical energy to emit and/or receive electromagnetic waves.

Communications 36, such as control signals, may be transmitted from a data processing system 38 (processing system 38) to the one or more logging tools 32, and communications 36, such as data signals related to the results/measurements of the one or more logging tools 32, may be returned to the data processing system 38 from the one or more logging tools 32. The data processing system 38 may be any electronic data processing system that can be used to carry out the systems and methods of this disclosure. For example, the data processing system 38 may include one or more processors 40, which may execute instructions stored in memory 42 and/or storage 44. The memory 42 and/or the storage 44 of the data processing system 38 may be any suitable article of manufacture that can store the instructions. In certain embodiments, the one or more processors 40 may include a microprocessor, a microcontroller, a processor module or subsystem, a programmable integrated circuit, a programmable gate array, a digital signal processor (DSP), or another control or computing device. In certain embodiments, the one or more processors 40 may include machine learning (ML) and/or artificial intelligence (AI) based processors, such as neural processing units (NPUs). Likewise, the one or more processors 40 may operate to implement a trained ML model as part of an AI processing system.

In certain embodiments, the memory 42 and storage 44 are implemented as one or more non-transitory computer-readable or machine-readable storage media. In certain embodiments, the memory 42 may include one or more different forms of memory, including semiconductor memory devices, such as dynamic or static random access memories (DRAMs or SRAMs), erasable and programmable read-only memories (EPROMs), electrically erasable and programmable read-only memories (EEPROMs) and flash memories. The storage 44 may include solid state drives, magnetic disks such as fixed, floppy and removable disks; other magnetic media including tape; optical media such as compact disks (CDs) or digital video disks (DVDs); or other types of storage devices. Note that the computer-executable instructions and associated data of the analysis module(s) may be provided on one computer-readable or machine-readable storage medium of the memory 42 or the storage 44, or alternatively, may be provided on multiple computer-readable or machine-readable storage media distributed in a large system having possibly plural nodes. Such computer-readable or machine-readable storage medium or media are considered to be part of an article (or article of manufacture), which may refer to any manufactured single component or multiple components. In certain embodiments, the storage 44 may be located either in the machine running the machine-readable instructions or may be located at a remote site from which machine-readable instructions may be downloaded over a network for execution.

As illustrated, the data processing system 38 may optionally also include a display 46, which may be any suitable electronic display, and may display images generated by the processor 40. The data processing system 38 may be a local component of the drilling system 10 (i.e., at the surface), within the one or more logging tools 32 (i.e., downhole), a device located proximate to the drilling operation, and/or a remote data processing device located away from the drilling system 10 to process downhole measurements in real time or sometime after the data has been collected. In some embodiments, the data processing system 38 may be a portable computing device (e.g., tablet, smart phone, or laptop) or a server remote from the drilling system 10. In some embodiments, the one or more logging tools 32 may store and process collected data in the BHA 28 or send the data to the surface for processing via communications 36 described above, including any suitable telemetry (e.g., electrical signals pulsed through the geological region 14 or mud pulse telemetry using the drilling fluid).

It should be noted that, although the discussion above relates to a drilling system, other downhole equipment or systems may employ the systems and methods of this disclosure. For example, a downhole tool with an acoustic tool conveyed by slickline, coiled tubing, wireline, or other delivery systems, may utilize the disclosed systems and methods.

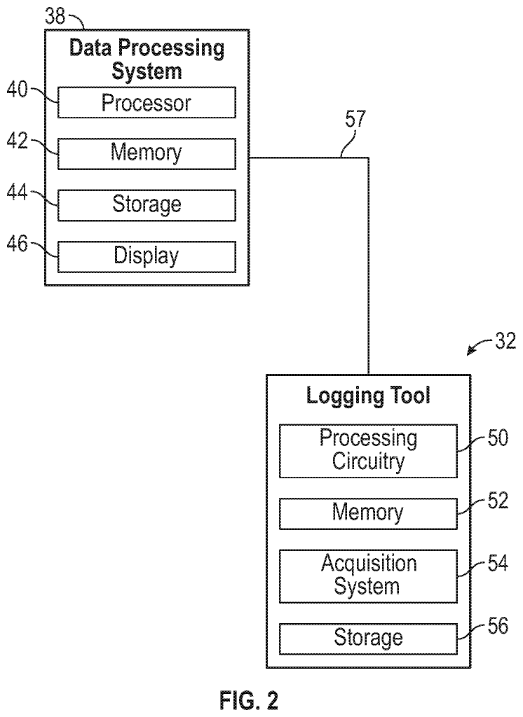

In one embodiment, operation of drilling system 10 may be controlled by a processor of the data processing system 38. For example, FIG. 2 illustrates a block diagram of the data processing system 38 that is communicatively coupled to the one or more logging tools 32. In the illustrated embodiment, a logging tool 32 includes processing circuitry 50, memory 52, an acquisition system 54, and storage 56. In some embodiments, the processing circuitry 50 may include an ASIC (application specific integrated circuit), field programmable gate array (FPGA), a micro control unit (MCU), a digital signal processor (DSP), and the like that operate on high integer value data (e.g., having 16-bit resolution, 32-bit resolution, 64-bit resolution, etc.). In some embodiments, the logging tool 32 communicates with the data processing system 38 via a data cable 57, telemeter, or other suitable techniques. For example, the logging tool 32 may communicate measurements obtained by a one or more sensors (or meters) as part of the acquisition system 54. In turn, a processor 40 of the surface control system may determine certain parameters (e.g., fluid-filled porosity, pore size, water saturation, relative permeability, T₂ relaxation times, and the like) based on the measurements. In such embodiments, the acquisition system 54 may include an emission source (e.g., an antenna) to acquire, obtain, or otherwise measure measurements.

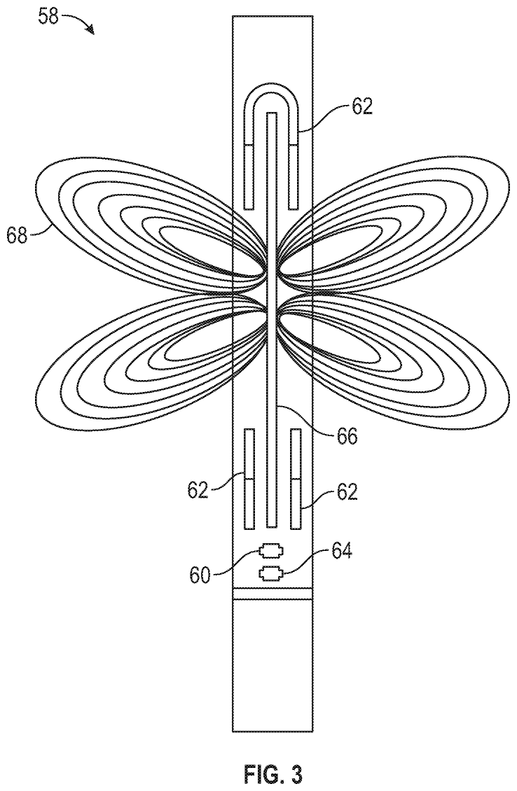

FIG. 3 illustrates a schematic view of an example nuclear magnetic resonance (NMR) logging tool 58 that can be utilized as the logging tool 32. It should be noted that the components and/or geometries of the NMR logging tool 58 may be other than as illustrated, and the schematic view depicted in FIG. 3 is merely for explanatory purposes. The NMR logging tool 58 (e.g., nuclear magnetic resonance logging tool 58), as illustrated, includes permanent magnets 62, which operate to produce a static magnetic field (B₀) (not illustrated). It should be noted that the permanent magnets 62 may possess geometries other than as illustrated (e.g., cylindrical “Jasper Jackson” structures, “saddle point” design, etc.). As the NMR logging tool 58 passes through the surrounding formation, the permanent magnets 62 may align the magnetic moments of hydrogen nuclei within the surrounding pores with the magnetic field B₀. Furthermore, the NMR logging tool 58 includes a radio-frequency (RF) antenna 66, which may operate as both a transmitter (e.g., transmitting RF pulses into the surrounding formation) and a receiver (e.g., detecting the weaker electromagnetic fields emitted by hydrogen nuclei as they relax). In some embodiments, the antenna 66 may take the form of a copper coil. The magnetic field (B₁) 68 may be emitted from the antenna 66 into the surrounding formation. The NMR logging tool 58 may further include downhole electronics such as the controller 60 and/or telemetry device 64. The controller 60 may include a RF pulse circuit, which may operate to generate the pulse sequences (e.g., RF pulse sequences, such as the Carr-Purcell-Meiboom-Gill (CPMG) sequence) used to manipulate nuclear spins of local hydrogen nuclei. The pulse sequences generated by the controller t 60 may be bursts of current passed through the antenna 66 to produce the magnetic field 68. The controller 60 may further tune the frequency of such pulse sequences to match the Larmor frequency, which may be dependent upon the static magnetic field B₀, produced by the permanent magnets 62. In some embodiments, the controller 60 may rapidly switch between different RF frequencies to enable faster and more detailed logging operations. Immediately after the pulse sequence, the antenna 66 may “listen” to the protons (e.g., hydrogen nuclei) returning to alignment; as the positive charges (e.g., protons) return to alignment, the movement (e.g., precession) of the charges may induce a faint voltage in the antenna 66. The downhole electronics (e.g., the controller 60 and/or the telemetry device 64) may also include a preamplifier, which may operate to amplify the micro-voltages induced in the antenna 66 and/or filter background borehole noise. These amplified voltages may then be digitized by the controller 60 and passed to the surface by the telemetry device 64. For instance, the telemetry device 64 may pass the digitized data from the controller 60 to the surface via a wired connection or the like, such as to the data processing system 38 of FIG. 2 via data cable 57. The digitized data may be interpreted at the surface and used in further natural resource operations (e.g., operational decision-making, wellsite planning and/or sizing, risk assessment, and the like).

Returning to FIG. 2, in certain embodiments, the data processing system 38 may include one or more analysis modules (e.g., a program of computer-executable instructions and associated data) that may be configured to perform various functions of the embodiments described herein. In certain embodiments, to perform these various functions, the one or more analysis modules may be executed on one or more processors 40 of the data processing system 38, which may be connected to memory 42 and storage 44 in which the one or more analysis modules may be stored.

In certain embodiments, the computer-executable instructions of the one or more analysis modules, when executed by the one or more processors 40, may cause the one or more processors 40 to generate one or more models (e.g., forward model, inverse model, mechanical model, and so forth). Such models may be used by the processing system 38 to predict values of operational parameters that may or may not be measured (e.g., using gauges, sensors, and so forth) during well operations.

One technique for generation of the models for a formation by the processing system may include acquiring data via the logging tool 32 and transmitting that data to the processing system 38 for interpretation. This interpretation of the measured data by the processing system 38 can include performance of an inversion by the processing system 38 in which measured data received from the logging tool 32 is utilized to infer a parameter to be calculated using a forward model (e.g., determining inputs from outputs, such as determining the formation-specific parameters from the measured T₂ distributions and a model that predicts T₂ distributions). This can include iteration utilizing the forward model until a difference (or error) between a measured data and the parameter being estimated to generate an output is minimized (or is less than a predetermined threshold value). However, in other embodiments, the data interpretation typically performed by the data processing system 38 can instead be transferred from the surface to the logging tool 32 itself. That is, both the measurement of data as well as its interpretation may be performed directly in the downhole tool (e.g., the logging tool 32). Once generated, the interpretation results can be sent from the downhole tool to the surface (e.g., to the data processing system 38).

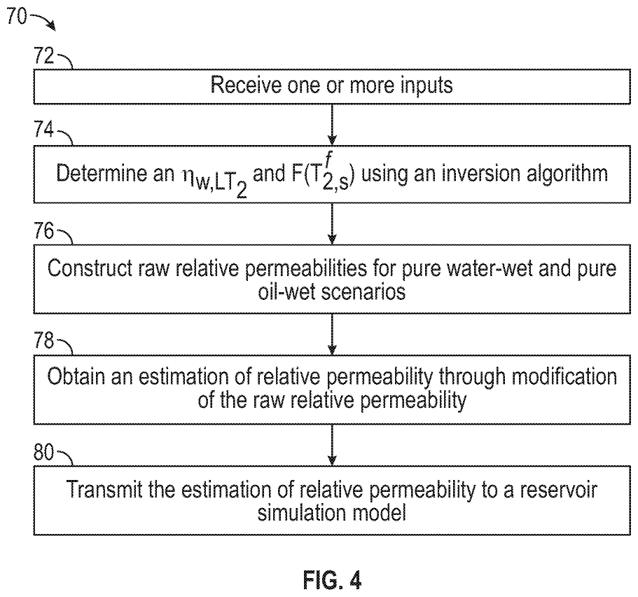

Referring now to FIG. 4, FIG. 4 illustrates a flow chart 70 to estimate the relative permeability of a geological region utilizing the pore size or throat distribution and the wettability properties. In some embodiments, one or blocks of the process represented by flow chart 70 can be performed by one or more processors (e.g., processor 40) executing instructions stored in memory (e.g., memory 42) to perform the techniques described in conjunction with FIG. 4. One or more blocks of the flow chart 70 will be discussed as being performed by the data processing system 38 of FIG. 1, however, the one or more blocks of the flow chart 70 can additionally and/or alternatively be performed by a cloud computing device or a remote computing device.

At block 72, the data processing system 38 may receive one or more inputs. The one or more inputs may include one or more NMR T₂ relaxation signals, a water saturation, S_{w}, the bulk water T₂ relaxation time, T_{2,b,w}, the bulk oil T₂ relaxation time distribution, G(T_{2,b,o}). The one or more NMR T₂ relaxation signals may obtained via a direct measurement from the NMR downhole logging tool 58 (e.g., the one or more NMR T₂ relaxation signals can be measured data). More specifically, the NMR logging tool 58 may acquire the T₂ relaxation signals data by emitting radio frequency pulses (e.g., a CPMG pulse sequence) to create a train of spin echoes (e.g., an echo train). The water saturation, S_{w}, input may be a fraction of pore volume occupied by water and, for example, be derived from petrophysical interpretation of the NMR downhole logging tool's 58 data by use of Equations (1)-(6) described below (e.g., the water saturation, S_{w}, can be measured data).

The bulk water T₂ relaxation time, T_{2,b,w}, may be the intrinsic transverse relaxation time of water in its “free” state (e.g., unaffected by rock surfaces or magnetic gradients) and may be a standard lab-derived value (e.g., the bulk water T₂ relaxation time, T_{2,b,w}, can be auxiliary input data). The bulk oil T₂ relaxation time distribution, G(T_{2,b,o}), may represent intrinsic relaxation times of all the different hydrocarbon molecules within a specific crude oil sample and may be obtained through surface or in-situ (downhole) measurements (e.g., the bulk oil T₂ relaxation time distribution, G(T_{2,b,o}), can be measured data).

Block 72 can additionally include defining model parameters, including suitable exponent and critical time, α and T_{c}, respectively, for defining fluid distribution pattern and wettability characteristics as those discussed above with respect to Equations (4) and (5) described below. The defining of α and T_{c} can be either done receiving inputted predetermined values or by generation of the model parameters by correlation to mineralogy. The model parameter exponent α may control the sharpness of saturation transition around the characteristic time, T_{c}. The value α may be dependent on geological regions, however, the value α may fall in the range of approximately 2-3. In the absence of a further benchmark, the value α may be 2.5 as a default value. The characteristic time T_{c} may be expected to have a stronger mineralogy dependence due to the variation of surface relaxivity associated with mineralogy. However, the typical range of T_{c} may fall between for example, approximately 10-150 ms. T_{c} and α can be considered modeled data and, thus, may be auxiliary input data. In this manner, block 72 represents acquisition of input data as both measured NMR data and auxiliary input data (e.g., field and/or lab data) as well as receipt or generation of model data

The data processing system 38 may perform processing (e.g., in the fast diffusion regime) of one or more of the inputs from block 72 using Equation (1), as seen below.

$$\frac{1}{{T}_{2}^{f}} = \frac{1}{{T}_{2 , b , w}} + {ρ}_{w} \frac{A}{V} = \frac{1}{{T}_{2 , b , w}} + \frac{1}{{τ}_{2 , s}^{f}} , with {T}_{2 , s}^{f} = \frac{r}{c {ρ}_{w}} . \qquad ( 1 )$$

In Equation (1),

$${T}_{2}^{f}$$

is the T₂ relaxation time of the fully-water saturated pore, T_{2,b,w} is the bulk water/brine T₂ relaxation time, A is the pore surface area, and V is the pore volume. In addition,

$${T}_{2 , s}^{f}$$

is the surface T₂ relaxation for the fully water saturated pore with an effective size r [μm/s]. The geometric factor c=3, 2, 1 for spherical, tubular, and flake-like pores. As such, the surface relaxation time,

$${T}_{2 , s}^{f} ,$$

for the fully water saturated pore may be directly proportional to the pore size, up to a multiplication constant of 1/cρ_{w}.

In some embodiments, both oil and brine may be present in a pore and contribute to the T₂ relaxation signals. Thus, the data processing system 38 may determine the relaxation times of water,

$${T}_{2 , w} ( {T}_{2 , s}^{f} ) , and of oil , {T}_{2 , o} ( {T}_{2 , s}^{f} ) ,$$

residing in the pore with the fully water saturated surface relaxation time,

$${T}_{2 , s}^{f} ,$$

using Equations (2) and (3) below.

$$\frac{1}{{T}_{2 , w} ( {T}_{2 , s}^{f} )} = \frac{1}{{T}_{2 , b , w}} + {ρ}_{w} \frac{A Ω ( {T}_{2 , s}^{f} )}{V Φ ( {T}_{2 , s}^{f} )} = \frac{1}{{T}_{2 , b , w}} + \frac{Ω ( {T}_{2 , s}^{f} )}{Φ ( {T}_{2 , s}^{f} )} \frac{1}{{T}_{2 , s}^{f}} , \qquad ( 2 )$$

$$\frac{1}{{T}_{2 , o} ( {T}_{2 , s}^{f} )} = \frac{1}{{T}_{2 , b , o}} + {ρ}_{o} \frac{A [ 1 - Ω ( {T}_{2 , s}^{f} ) ]}{V [ 1 - Φ ( {T}_{2 , s}^{f} ) ]} = \frac{1}{{T}_{2 , b , o}} + \frac{1}{{γ}_{w / o}} \frac{1 - Ω ( {T}_{2 , s}^{f} )}{1 - Φ ( {T}_{2 , s}^{f} )} \frac{1}{{T}_{2 , s}^{f}} . \qquad ( 3 )$$

In Equations (2) and (3),

$$Ω ( {T}_{2 , s}^{f} )$$

is the water-wetting surface fraction and

$$Φ ( {T}_{2 , s}^{f} )$$

is the water volume fraction in the pore with the fully water saturated surface relaxation time,

$${T}_{2 , s}^{f} .$$

The γ_{w/o}=ρ_{w}/ρₒ is the surface relaxivity ration between water and oil Equations (2) and (3) may be understood as the surface relaxation contribution to the overall T₂ values that may be affected by the ration of fluids residing in the pore and contacted surface area. That is, the bulk water and oil relaxation time,

$${T}_{2 , w} ( {T}_{2 , s}^{f} )$$

and

$${T}_{2 , o} ( {T}_{2 , s}^{f} )$$

may have a distribution. In some embodiments, the bulk oil/hydrocarbon relaxation time may have the distribution G(T_{2,b,o}).

Based on Equations (2) and (3), the data processing system 38 may predict the T₂ relaxation signal, either in a time domain or in the form of a T₂ distribution, of a formation partially saturated with brine and oil, given that the T₂ distribution.

$$F ( {T}_{2 , s}^{f} ) ,$$

of the same formation saturated fully with brine is known. The data processing system 38 may normalize the overall integration of the function

$$F ( {T}_{2 , s}^{f} )$$

to one. In the present embodiment, the data processing system 38 may parameterize

$$F ( {T}_{2 , s}^{f} )$$

by

$${T}_{2 , s}^{f}$$

rather than

$${T}_{2}^{f}$$

because

$${T}_{2}^{f}$$

may be easily translated into the pore size distribution. To predict the raw relative permeability, the data processing system may use Equations (4) and (5) to define the bulk water and oil relaxation times (e.g., the distribution), the ratio γ_{w/o}, and the functional forms of

$$Ω ( {T}_{2 , s}^{f} )$$

and

$$Φ ( {T}_{2 , s}^{f} ) .$$

$$Φ ( {T}_{2 , s}^{f} ) = \frac{1 + {{S}_{w , L {T}_{2}} [ \frac{{T}_{2 , s}^{f}}{{T}_{c}} ]}^{α}}{1 + {[ \frac{{T}_{2 , s}^{f}}{{T}_{c}} ]}^{α}} , \qquad ( 4 )$$

$$Ω ( {T}_{2 , s}^{f} ) = \frac{1 + {{η}_{w , {LT}_{2}} [ \frac{{T}_{2 , s}^{f}}{{T}_{c}} ]}^{α}}{1 + {[ \frac{{T}_{2 , s}^{f}}{{T}_{c}} ]}^{α}} \qquad ( 5 )$$

In Equations (4) and (5), T_{c} is the characteristic time that determines the inflection point in the

$${T}_{2 , s}^{f}$$

space, and α is the exponent controlling the sharpness of transition from fully-saturated smaller pores

$$( {T}_{2 , s}^{f} ≪ {T}_{c} ) ,$$

to partially saturated larger pores

$$( {T}_{2 , s}^{f} ≫ {T}_{c} )$$

at the water saturation level, S_{w,LT}_{₂}. The water-wetting surface fraction function,

$$Ω ( {T}_{2 , s}^{f} ) ,$$

in Equation (5) may use the same parameterization as those for

$$Φ ( {T}_{2 , s}^{f} )$$

in Equation (4), however, the water-wetting surface fraction may be η_{w,LT}_{₂} for larger pores. This may be due to the physical processes enabling wettability alteration being ultimately correlated to the presence of oil in specific pores.

The functions defined above may be correlated to physically measurable and well-defined quantities. For instance, the total water saturation, S_{w}, of the formation may be defined by Equation (6) below.

$${S}_{w} = {\int }_{0}^{∞} F ( {T}_{2 , s}^{f} ) Φ ( {T}_{2 , s}^{f} ) d {T}_{2 , s}^{f} \qquad ( 6 )$$

In some embodiments, the data processing system 38 may obtain the total water saturation through petrophysical interpretations from other logging tools. In other embodiments, the S_{w} may be used as an input to determine the value of S_{w,LT}_{₂} from Equation (6) when

$$F ( {T}_{2 , s}^{f} )$$

is known and α and T_{c} are predetermined. Although the water-wetting surface fraction for larger pores, η_{w,LT}_{₂}, may be a good indicator for wettability, the smaller value of η_{w,LT}_{₂} may indicate a more oil-wet geological formation. Thus, the overall wettability characteristic index may be defined in Equation (7) below where

$${\int }_{0}^{∞} F ( {T}_{2 , s}^{f} ) d {T}_{2 , s}^{f} = 1 .$$

$${I}_{W} = {\int }_{0}^{∞} F ( {T}_{2 , s}^{f} ) Ω ( {T}_{2 , s}^{f} ) d {T}_{2 , s}^{f} - {\int }_{0}^{∞} F ( {T}_{2 , s}^{f} ) [ 1 - Ω ( {T}_{2 , s}^{f} ) ] d {T}_{2 , s}^{f} = 2 {\int }_{0}^{∞} F ( {T}_{2 , s}^{f} ) Ω ( {T}_{2 , s}^{f} ) d {T}_{2 , s}^{f} - 1 \qquad ( 7 )$$

In some embodiments, the data processing system 38 may use forward models to predict the normalized NMR magnetization relaxation signals for the partially saturated formation may be computed as the sum of brine and oil contribution as M(t)=M_{w}(t)+Mₒ(t) using Equation (8) and (9) below.

$${M}_{w} ( t ) = {\int }_{0}^{∞} F ( {T}_{2 , s}^{f} ) Φ ( {T}_{2 , s}^{f} ) {e}^{- \frac{t}{{T}_{2 , w} ( {T}_{2 , s}^{f} )}} d {T}_{2 , s}^{f} \qquad ( 8 )$$

$$( 9 )$$

$${M}_{o} ( t ) = {\int }_{0}^{∞} d {T}_{2 , b , o} G ( {T}_{2 , b , o} ) {\int }_{0}^{∞} F ( {T}_{2 , s}^{f} ) [ 1 - Φ ( {T}_{2 , s}^{f} ) ] {e}^{- \frac{t}{{T}_{2 , o} ( {T}_{2 , s}^{f} , {T}_{2 , b , o} )}} d {T}_{2 , s}^{f}$$

In Equations (8) and (9), the T_{2,w} and T_{2,o} may be given by Equations (2) and (3) above. The M(t) computed may match with the measured magnetization relaxation, \tilde{M}(t), to infer the η_{w,LT}_{₂} and

$$F ( {T}_{2 , s}^{f} ) .$$

From the computed M(t), the corresponding T₂ distribution,

$${F}_{p} ( {T}_{2 , s}^{f} ) ,$$

may be obtained for partially saturated geological formation by accounting for the effects of pore size distribution, fluid distribution, and wettability. In some embodiments, the

$${F}_{p} ( {T}_{2 , s}^{f} )$$

may be obtained directly from

$$F ( {T}_{2 , s}^{f} )$$

with the water volume function

$$Φ ( {T}_{2 , s}^{f} )$$

and the bulk oil T₂ distribution

$$G ( {T}_{2 , b , o} ) ,$$

utilizing Equations (2) and (3) without using time domain transformations. In the present embodiment, the computed Fₚ(T₂) may be matched with the measured and processed \tilde{F}ₚ(T₂) to infer the optimized η_{w,LT}_{₂} and

$$F ( {T}_{2 , s}^{f} ) .$$

Although the magnetization relaxation M(t) and the T₂ distribution, Fₚ(T₂), may be described as a continuous function, the NMR magnetization relaxation signal may be measured in a discrete echo spacing, t_{E}, with nₜ echoes, while T₂ may be discretized in N_{T}_{₂} logarithmic spacings with the desired T₂ range. The total magnetization relaxation measurement time may be tₜₒₜₐₗ=t_{E}×nₜ. In some embodiments, t_{E} may be the range of 100-2000 μs, nₜ may be the range of 4096-8192, and N_{T}_{₂} may be the range of 80-120, logarithmically spaced between 0.1-10000 ms. Thus, the integration of the exponential decay kernal, such as those in Equations (8) and (9), may be better discretized as a matrix kernal, K, where its columns represent discretized exponential decay at different T₂. For example, if one has nₜ echoes in the measurement with T₂ spaced in N_{T}_{₂} steps, the kernal K may be a nₜ×N_{T}_{₂} matrix. Thus, the magnetization relaxation M and the T₂ distribution Fₚ in the discretized spacing may be related by M=KFₚ. Here, M is a nₜ×1 column vector and Fₚ is a N_{T}_{₂}×1 column vector. The Kernal matrix K may be decomposed and diagonalized through the singular value decompression (SVD) such that K=UΣV^{T}, where Σ is a diagonal matrix with nₛ non-zero singular values sᵢ in a descending order. U and V are nₜ×nₛ matrices, respectively. T superscript, T, denotes the transpose of the matrix. For the exponentially decaying Kernal, because the singular values sᵢ fade rapidly, there may only be a need to keep nᵣ=8-10 to capture the majority of the features of the measurement. Thus, the nᵣ singular values and the first nᵣ columns of U and V matrices.

As such, at block 74, the data processing system 38 may determine η_{w,LT}_{₂} and

$$F ( {T}_{2 , s}^{f} )$$

using an inversion algorithm. The data processing system 38 may compress the measurement time series into a column vector \tilde{d} with nᵣ elements as shown in Equation (10).

d=U_{T}M=ΣV^{T}Fₚ (10)

In the present embodiment, the data processing system 38 may infer the optimized η_{w,LT}_{₂} and

$$F ( {T}_{2 , s}^{f} )$$

with the compressed vector dₚ computed from modeled partially saturated geological formations with the compressed vector \tilde{d}ₚ obtained from measurements from the NMR downhole logging tool 58. As such, from Equation (10), the data processing system 38 may translate the time domain data and the T₂ distribution into compressed vectors for data comparison.

As illustrated above, it may be possible to use a set of modeling equations (e.g., Equations (2)-(6)) to connect the T₂ distribution

$$F ( {T}_{2 , s}^{f} ) ,$$

of the formation fully saturated with brine to the T₂ distribution, Fₚ(T₂). In field applications, however, there may not be information regarding

$$F ( {T}_{2 , s}^{f} )$$

As such, in some embodiments, data processing system 38 may measure and process the magnetization relaxation \tilde{M}(t) of partially saturated geological formations to obtain \tilde{F}ₚ(T₂). Thus, the data processing system 38 may infer

$$F ( {T}_{2 , s}^{f} )$$

and the water-wetting surface fraction at large pores, η_{w,LT}_{₂} based on the \tilde{M}(t) or \tilde{F}ₚ(T₂), auxiliary inputs, and predefined modeling parameters.

In the present embodiment, the data processing system 38 may infer the optimized η_{w,LT}_{₂} and

$$F ( {T}_{2 , s}^{f} )$$

using Equation (11) recited below.

$$arg {min}_{{η}_{w , L {T}_{2}} , F ( {T}_{2 , s}^{f} )} ( {\vert {\tilde{d}}_{p} - d ( {η}_{w , {LT}_{2}} , F ( {T}_{2 , s}^{f} ) ) \vert}^{2} + Reg ) \qquad ( 11 )$$

In Equation (11), \tilde{d}ₚ is the compressed data vector form the measured signals,

$$d ( {η}_{w , {LT}_{2}} , F ( {T}_{2 , s}^{f} ) )$$

is from the predicted signals, and Reg represents any prior regulations Equation (11) may imply the use of a L₂-norm for minimizing the distance between \tilde{d}ₚ and

$$d ( {η}_{w , {LT}_{2}} , F ( {T}_{2 , s}^{f} ) ) .$$

In some embodiments, other reasonable cost functions, such as L₁-norm may also be used to minimize the distance between \tilde{d}ₚ and

$$d ( {η}_{w , {LT}_{2}} , F ( {T}_{2 , s}^{f} ) ) .$$

As mentioned above, the variation of

$$F ( {T}_{2 , s}^{f} )$$

may further estimate the relative permeability. Thus, in some embodiments, the data processing system may assume

$$F ( {T}_{2 , s}^{f} )$$

takes the sum of N_{G} Gaussian distributions in the logarithmic space. In terms of λ=log₁₀

$${T}_{2 , s}^{f} ,$$

Equation (12) may be generated.

$$F ( λ ) = {\sum }_{j = 1}^{{N}_{G}} {f}_{j} \frac{{e}^{- \frac{{( λ - {μ}_{j} )}^{2}}{{2 [ {σ}_{j} ]}^{2}}}}{\sqrt{2 π} {σ}_{j}} \qquad ( 12 )$$

In Equation (12), μⱼ, σⱼ, and fⱼ are mean, variance, and weight, respective of the j-th Gaussian function. The summation of weights is Σⱼfⱼ=1 for normalization. Thus, there may be 3N_{G}−1 free parameters.

At block 76, the data processing system 38 may construct raw relative permeabilities for pure water-wet and pure oil-wet scenarios. The data processing system 38, may generate the raw relative permeability from the saturated surface T₂ relaxation distribution,

$$F ( {T}_{2 , s}^{f} ) .$$

That data processing system may use Equations (13) and (14) to calculate the relative permeabilities of the wetting fluid, κ_{r,wet}, and of the non-wetting fluids, κ_{r,nonwet}. Equations (13) and (14) may describe the correlation between the relative permeability and the wetting fluid saturation fraction, S_{wet}, as a function of capillary pressure, P_{c}.

$${κ}_{r , wet} ( {S}_{wet} ) ≡ \frac{{κ}_{wet} ( {S}_{wet} )}{{κ}_{0}} = {[ {S}_{wet} ]}^{2} \frac{{\int }_{0}^{{S}_{w e t}} \frac{d {S}_{wet}^{′}}{{P}_{c}^{2}}}{{\int }_{0}^{1} \frac{{dS}_{wet}^{′}}{{P}_{c}^{2}}} \qquad ( 13 )$$

$${κ}_{r , nonwet} ( {S}_{wet} ) ≡ \frac{{κ}_{n o nwet} ( {S}_{wet} )}{{k}_{0}} = {[ 1 - {S}_{wet} ]}^{2} \frac{{\int }_{{S}_{w e t}}^{1} \frac{d {S}_{wet}^{′}}{{P}_{c}^{2}}}{{\int }_{0}^{1} \frac{{dS}_{wet}^{′}}{{P}_{c}^{2}}} \qquad ( 14 )$$

In Equations (13) and (14), κ_{r,wet}(S_{wet}) and κ_{r,nonwet}(S_{wet}) are the permeability of the wetting and of the non-wetting fluids at the wetting fluid saturation level, S_{wet}. The relative permeability may be normalized to the absolute permeability Ko when the whole geological region is fully saturated by one type of fluid. Additional formation properties may be required to modify the raw relative permeability to reach a final estimation of relative permeability.

In some embodiments, a relation between the capillary pressure, P_{c}, and the wetting fluid saturation fraction S_{wet} may be required. The non-wetting fluid may flow into pore networks by increasing the capillary pressure, which in turn reduces the saturation of wetting fluids. Equation (15) may describe the summation of multiple error functions.

$${S}_{wet} ( {P}_{c} ) = {\sum }_{j = 1}^{{N}_{G}} \frac{{f}_{j}^{c}}{2} [ 1 - Erf ( \frac{{log}_{10} ( {P}_{c} ) - {μ}_{j}^{c}}{\sqrt{2} {σ}_{j}^{c}} ) ] \qquad ( 15 )$$

In Equation (15), the Erf is the error function. Mathematically, Equation (15) is a cumulative distribution function with a probability distribution function in the logarithmic space log₁₀(P_{c}) as described in Equation (16) below.

$$\frac{d {S}_{wet}}{d {log}_{10} ( {P}_{c} )} = - {\sum }_{j = 1}^{{N}_{G}} {f}_{j}^{c} \frac{{e}^{- \frac{{[ {log}_{10} ( {P}_{c} ) - {μ}_{j}^{c} ]}^{2}}{{2 [ {σ}_{j}^{c} ]}^{2}}}}{\sqrt{2 π} {σ}_{j}^{c}} \qquad ( 16 )$$

In Equation (16), fⱼ, μⱼ, and σⱼ are weight, mean, and variance of the j-th Gaussian function of the probability distribution function.

The saturation may change with respect to the capillary pressure and may be controlled by the pore throat size and distribution. The pore throat size and capillary pressure may be inversely related such that P_{c}∝rₚ⁻¹, where rₚ is the radius of the pore throat. In the geological formation, the pore throat and pore size distribution may be assumed to be linearly proportional to each other such that r∝rₚ. As stated above, the fully-water saturation surface T₂ relaxation time may also be proportional to the pore size,

$${T}_{2 , s}^{f} ∝ r .$$

These relationships may connect Equations (12) and (16). Thus, Equations (12) and (16) may show that

$${f}_{j}^{c} = {f}_{j} , {σ}_{j}^{c} = {σ}_{j} , and {μ}_{j}^{c} = - {μ}_{j} + C$$

with C being a common constant independent form j. That is, once the Gaussian parameters associated with the F(λ) in Equation (12) is identified, the Gaussian parameters may be directly translated to Equations (15) and (16). As such, the data processing system 38 may then evaluate the raw relative permeability using Equations (17) and (18) as seen below.

$${κ}_{r , wet} ( {P}_{c} ) = {( {S}_{wet} ( {P}_{c} ) )}^{2} \times {\sum }_{j}^{{N}_{G}} \frac{{W}_{j}}{2} [ 1 - Erf ( \frac{ln {P}_{c} - {\overline{μ}}_{j}^{c} + 2 {\overline{{σ}_{j}}}^{c}}{\sqrt{2} {\overline{{σ}_{j}}}^{c}} ) ] \qquad ( 17 )$$

$${κ}_{r , nonwet} ( {P}_{c} ) = {( 1 - {S}_{wet} ( {P}_{c} ) )}^{2} \times {\sum }_{j}^{{N}_{G}} \frac{{W}_{j}}{2} [ 1 + Erf ( \frac{ln {P}_{c} - {\overline{μ}}_{j}^{c} + 2 {\overline{{σ}_{j}}}^{c}}{\sqrt{2} {\overline{{σ}_{j}}}^{c}} ) ] \qquad ( 18 )$$

Thus, using Equations (17) and (18), the κ_{r,wet}(P_{c}), κ_{r,nonwet}(P_{c}), and S_{wet}(P_{c}) at varying values of P_{c} coupled with the S_{wet}(P_{c}) calculated in Equation (15) the κ_{r,wet}(S_{wet}) and κ_{r,nonwet}(S_{wet}) may be calculated.

At block 78, the data processing system may obtain an estimation of relative permeability through modification of the raw relative permeability found at block 76. The data processing system 38 may incorporate the wettability characteristics inferred from the T₂ distribution of the partially saturated formation, Fₚ(T₂). The data processing system 38 may take the relative permeability of the purely water-wet and of the purely oil-wet formation to serve as two end scenarios. As such, the relative permeability of the mixed-wet geological region may be obtained from an interpolation between the two end scenarios. To determine the relative permeability of the mixed-wet geological region, the data processing system 38 may provide additional mixed-wet properties may be provided. More specifically, the data processing system 38 may recall the wettability characteristic function from Equation (6) that is governed by the water-wetting surface fraction, η_{w,LT}_{₂} for large pores. In the present embodiment, the data processing system 38 may define an effective water-wetting influence fraction, f_{ww}, on water to estimate the fraction of water influenced by the water-wet surface using Equation (19) below.

$${f}_{w w} ( {S}_{w} ) = \frac{1}{{S}_{w}} [ \begin{matrix}{S}_{w , i} + \frac{{S}_{w} - {S}_{w , i}}{{S}_{w}} \times … \\ d {log}_{10} ( {T}_{2 , s}^{f} ) [ F ( {T}_{2 , s}^{f} ) \times Φ ( {T}_{2 , s}^{f} , {S}_{w} ) \times Ω ( {T}_{2 s}^{f} ) ]\end{matrix} ] \qquad ( 19 )$$

In Equation (19), the data processing system 38 may assume that all irreducible water is always in contact with water-wet surface. Thus, f_{ww}(S_{w,i})=1 by default. The integration weighted by

$$\frac{{S}_{w} - {S}_{w , i}}{{S}_{w}}$$

may account for how much the rest of the water is influenced by water-wet surfaces.

With f_{ww}(S_{w}) defined at different saturations, the raw water relative permeability of the mixed-wet geological formation may be phenomenologically defined from the raw water relative permeabilities,

$${κ}_{r , water}^{W W} ( {S}_{w} ) and {κ}_{r , water}^{OW} ( {S}_{w} )$$

of the water-wet (WW) and of the oil-wet (OW) end scenarios respectively in Equations (20). Similarly, Equation (21) may define the raw oil relative permeabilities, given the raw water relative permeabilities of the two end scenarios.

$${κ}_{r , water}^{M W} ( {S}_{w} ) = {f}_{w w} ( {S}_{w} ) \times {κ}_{r , water}^{W W} ( {S}_{w} ) + [ 1 - {f}_{w w} ( {S}_{w} ) ] \times {κ}_{r , water}^{O W} ( {S}_{w} ) \qquad ( 20 )$$

$${κ}_{r , oil}^{M W} ( {S}_{w} ) = {f}_{w w} ( {S}_{w} ) \times {κ}_{r , oil}^{W W} ( {S}_{w} ) + [ 1 - {f}_{w w} ( {S}_{w} ) ] \times {κ}_{r , oil}^{O W} ( {S}_{w} ) \qquad ( 21 )$$

Equations (20) and (21) may be graphically show the raw relative permeability of the mixed-wet geological formation. Thus, the graphical representations of Equations (20) and (21) may be interpolated to find the raw relative permeability of the mix-wet geological formation based on the water saturation, S_{w}, and the wettability parameter, η_{w,LT}_{₂}.

The data processing system 38 may then modify the raw relative permeability with one or more additional inputs to generate the estimated relative permeability. The one or more additional inputs may include an irreducible water saturation, S_{w,i}, (e.g., water content remaining in pores of a formation subsequent to displacement of hydrocarbons from the pores), typically held by capillary forces on rock surfaces and a residual oil fraction, Sₒᵣ (e.g., hydrocarbons remaining in the pores of a formation subsequent to the displacement of hydrocarbons from the pores). The data processing system 38 may cut off the raw relative permeability in the formation when S_{w}<S_{w,i} because the water saturation may not be reduced further. The data processing system 38 may cut off the raw relative permeability in the formation when S_{w}>1−Sₒᵣ, because the oil saturation may not be reduced further. The data processing system 38 may linearly re-scale the raw relative permeability into to range S_{w,i}<S_{w}<1−Sₒᵣ. The data processing system 38 may then renormalize the raw relative permeability with respect to the value of permeability of oil at irreducible water saturation, κₒ(S_{w,i}) to define the estimated relative permeability.

A block 80, the data processing system 38 may transmit the estimated relative permeability found at block 78 to a reservoir simulation model. The reservoir simulation model may predict how fluids (e.g., oil, water, gas, etc.) move through porous media of the geological formation over time and can be used in planning a hydrocarbon production operation (e.g., to determine a hydrocarbon production schedule, to produce hydrocarbons from the well without damaging the reservoir, and the like). That is, the relative permeability found at block 78 may be used in further modeling of the geological formation and/or the reservoir (e.g., developing simulations of the geological formation and/or the reservoir), as well as for decision-making (e.g., determining whether the accessible hydrocarbons of the reservoir justify constructing a well production system; if yes, determining how large of an investment in a well production system the reservoir justifies; determining whether the well production system should be developed for an oil-wet or a water-wet formation; determining and/or altering a hydrocarbon production schedule corresponding to the reservoir; etc.).

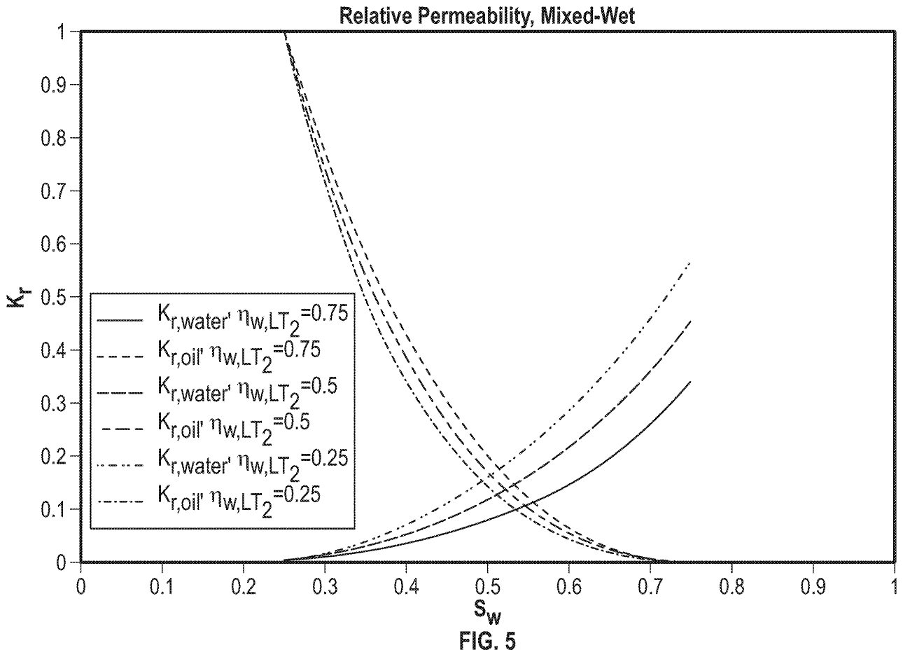

FIG. 5 illustrates a graphical representation of the estimated relative permeability with different levels of mix-wettability. The graphical representation may be interpolated to find the estimated relative permeability of a mixed-wet geological region based on the water saturation, S_{w}, and the wettability parameter, η_{w,LT}_{₂}. In FIG. 5, the estimated relative permeability may be found when η_{w,LT}_{₂}=0.75, 0.5, 0.25.

The techniques described herein allow for improvements to the generation of relative permeability. Using the techniques described herein, lab derived relative permeability (which can be lab derived but difficult, time consuming, and/or costly to measure) can be avoided. Additionally, as wettability status of a formation can change, a lab generated value for relative permeability may not represent what is occurring downhole. Instead, the present techniques allow for in situ measurement-based determinations of relative permeability that provide more accurate values for the generated relative permeability.

The subject matter described in detail above may be defined by one or more clauses, as set forth below.

A method, includes receiving one or more inputs, wherein the one or more inputs comprise input data measured in situ in a wellbore of a formation and auxiliary input data generated as lab data or based upon field data, defining a characteristic time (T_{c}) and an exponent value (α) that controls a sharpness of a transition from first sized pores of the formation to second sized pores of the formation as model parameters, generating a fully water saturated surface transverse (T₂) distribution utilizing the one or more inputs and the model parameters to realize a pore size distribution of the formation, minimizing a difference between a modeled T₂ relaxation response of a partially saturated formation and a measured T₂ relaxation response of the partially saturated formation to obtain a wettability characteristic index of the formation, constructing raw relative permeabilities for a pure water-wet formation scenario and a pure oil-wet formation scenario utilizing the pore size distribution of the formation as two end scenarios, obtaining a relative permeability estimation utilizing the raw relative permeabilities and the wettability characteristic index of the formation to account for influence of wettability changes to the formation by performing interpolation between the two end scenarios, and providing relative permeability estimation to a reservoir simulation model to characterize the formation.

A method of the preceding clause, further including obtaining the relative permeability estimation utilizing an irreducible water saturation (S_{w,i}) value of the formation and a residue oil fraction (Sₒᵣ) value of the formation.

A method of any of the preceding clauses, further including determining the S_{w,i} value based on constriction of water flow with pure geometric origin.

A method of any of the preceding clauses, further including constructing two pairs of raw relative permeabilities as the raw relative permeabilities.

A method of any of the preceding clauses, further including receiving one or more nuclear magnetic resonance (NMR) T₂ relaxation signals as a first portion of the input data measured in situ in the wellbore of the formation by an NMR tool.

A method of any of the preceding clauses, wherein the one or more NMR T₂ relaxation signals comprise partially saturated signals in a time domain \tilde{M}(t) or in a T₂ domain \tilde{F}ₚ(T₂).

A method of any of the preceding clauses, further including receiving a water saturation (S_{w}) value as a second portion of the input data measured in situ in the wellbore of the formation by the NMR tool.

A method of any of the preceding clauses, further including receiving a bulk oil/hydrocarbon T₂ relaxation time distribution, G(T_{2,b,o}), as a third portion of the input data measured in situ in the wellbore of the formation by the NMR tool.

A method of any of the preceding clauses, further including further comprising receiving a bulk water/brine T₂ relaxation time (T_{2,b,w}) as the auxiliary input data.

A method of any of the preceding clauses, further including defining the T_{c} and the α as predetermined values or by correlation to mineralogy of the formation.

A method of any of the preceding clauses, further including minimizing the difference between the modeled T₂ relaxation response and the measured T₂ relaxation response of the partially saturated formation in the time domain, in the T₂ domain, or in a singular value decomposition (SVD) compressed data domain.

A method of any of the preceding clauses, further including generating the fully water saturated surface T₂ distribution as a single Gaussian distribution or as a summation of multiple Gaussian distributions in a logarithmic T₂ space.

A system, including a nuclear magnetic resonance (NMR)-based logging tool configured to collect measured data in situ in a wellbore of a formation, and a data processing system in communication with the NMR-based logging tool, wherein the data processing system is configured to perform operations including receiving one or more inputs, wherein the one or more inputs include one or more NMR transverse (T₂) relaxation signals as a first portion of the measured data as partially saturated signals in a time domain \tilde{M}(t) or in a T₂ domain \tilde{F}ₚ(T₂), a water saturation (S_{w}) value as a second portion of the measured data, a bulk oil/hydrocarbon T₂ relaxation time distribution, G(T_{2,b,o}), as a third portion of the measured data, and a bulk water/brine T₂ relaxation time (T_{2,b,w}) as the auxiliary input data generated as lab data or based upon field data, defining a characteristic time (T_{c}) and an exponent value (α) that controls a sharpness of a transition from first sized pores from first sized pores of the formation to second sized pores of the formation as model parameters, generating a fully water saturated surface transverse (T₂) distribution utilizing the one or more inputs and the model parameters to realize a pore size distribution of the formation, minimizing a difference between a modeled T₂ relaxation response of a partially saturated formation and a measured T₂ relaxation response of the partially saturated formation to obtain a wettability characteristic index of the formation, constructing raw relative permeabilities for a pure water-wet formation scenario and a pure oil-wet formation scenario utilizing the pore size distribution of the formation as two end scenarios, obtaining a relative permeability estimation utilizing the raw relative permeabilities and the wettability characteristic index of the formation to account for influence of wettability changes to the formation by performing interpolation between the two end scenarios, and providing relative permeability estimation to a reservoir simulation model to characterize the formation.

A system of the preceding clause, wherein the data processing system is further configured to obtain the relative permeability estimation utilizing an irreducible water saturation (S_{w,i}) value of the formation and a residue oil fraction (Sₒᵣ) value of the formation, wherein the data processing system is further configured to determine the S_{w,i} value based on constriction of water flow with pure geometric origin.

A system of any of the preceding clauses, wherein the data processing system is further configured to construct two pairs of raw relative permeabilities as the raw relative permeabilities.

A system of any of the preceding clauses, wherein the data processing system is further configured to define the T_{c} and the α as predetermined values or by correlation to mineralogy of the formation.

A system of any of the preceding clauses, wherein the data processing system is further configured to minimize the difference between the modeled T₂ relaxation response and the measured T₂ relaxation response of the partially saturated formation in the time domain, in the T₂ domain, or in a singular value decomposition (SVD) compressed data domain.

A system of any of the preceding clauses, wherein the data processing system is further configured to generate the fully water saturated surface T₂ distribution as a single Gaussian distribution or as a summation of multiple Gaussian distributions in a logarithmic T₂ space.

A tangible, non-transitory, computer-readable medium comprising executable instructions that, when executed by processing circuitry, cause the processing circuitry to perform operations including receiving one or more inputs, wherein the one or more inputs include one or more nuclear magnetic resonance (NMR)-based logging tool measurement as measured data in situ in a wellbore of a formation, wherein the measured data comprises transverse (T₂) relaxation signals as a first portion of the measured data as partially saturated signals in a time domain \tilde{M}(t) or in a T₂ domain \tilde{F}ₚ(T₂), a water saturation (S_{w}) value as a second portion of the measured data, a bulk oil/hydrocarbon T₂ relaxation time distribution, G(T_{2,b,o}), as a third portion of the measured data, and a bulk water/brine T₂ relaxation time (T_{2,b,w}) as auxiliary input data generated as lab data or based upon field data, defining a characteristic time (T_{c}) and an exponent value (α) that controls a sharpness of a transition from first sized pores of the formation to second sized pores of the formation as model parameters generating a fully water saturated surface transverse (T₂) distribution utilizing the one or more inputs and the model parameters to realize a pore size distribution of the formation, minimizing a difference between a modeled T₂ relaxation response of a partially saturated formation and a measured T₂ relaxation response of the partially saturated formation to obtain a wettability characteristic index of the formation, constructing raw relative permeabilities for a pure water-wet formation scenario and a pure oil-wet formation scenario utilizing the pore size distribution of the formation as two end scenarios, obtaining a relative permeability estimation utilizing the raw relative permeabilities and the wettability characteristic index of the formation to account for influence of wettability changes to the formation by performing interpolation between the two end scenarios, and providing relative permeability estimation to a reservoir simulation model to characterize the formation.

The tangible, non-transitory, computer-readable medium of the preceding claim, wherein the executable instructions, when executed by the processing circuitry, cause the processing circuitry to obtain the relative permeability estimation utilizing an irreducible water saturation (S_{w,i}) value of the formation and a residue oil fraction (Sₒᵣ) value of the formation, wherein the data processing system is further configured to determine the S_{w,i} value based on constriction of water flow with pure geometric origin.

This written description uses examples to disclose the subject matter, including the best mode, and also to allow any person skilled in the art to practice the subject matter, including making and using any devices or systems and performing any incorporated methods. The patentable scope of the subject matter is defined by the claims and may include other examples that occur to those skilled in the art. Such other examples are intended to be within the scope of the claims if they have structural elements that do not differ from the literal language of the claims, or if they include equivalent structural elements with insubstantial differences from the literal language of the claims.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. A method, comprising:
receiving one or more inputs, wherein the one or more inputs comprise input data measured in situ in a wellbore of a formation and auxiliary input data generated as lab data or based upon field data;
defining a characteristic time (T_{c}) and an exponent value (α) that controls a sharpness of a transition from first sized pores of the formation to second sized pores of the formation as model parameters;
generating a fully water saturated surface transverse (T₂) distribution utilizing the one or more inputs and the model parameters to realize a pore size distribution of the formation;
minimizing a difference between a modeled T₂ relaxation response of a partially saturated formation and a measured T₂ relaxation response of the partially saturated formation to obtain a wettability characteristic index of the formation;
constructing raw relative permeabilities for a pure water-wet formation scenario and a pure oil-wet formation scenario utilizing the pore size distribution of the formation as two end scenarios;
obtaining a relative permeability estimation utilizing the raw relative permeabilities and the wettability characteristic index of the formation to account for influence of wettability changes to the formation by performing interpolation between the two end scenarios; and
providing relative permeability estimation to a reservoir simulation model to characterize the formation.

2. The method of claim 1, further comprising obtaining the relative permeability estimation utilizing an irreducible water saturation (S_{w,i}) value of the formation and a residue oil fraction (Sₒᵣ) value of the formation.

3. The method of claim 2, further comprising determining the S_{w,i} value based on constriction of water flow with pure geometric origin.

4. The method of claim 1, further comprising constructing two pairs of raw relative permeabilities as the raw relative permeabilities.

5. The method of claim 1, further comprising receiving one or more nuclear magnetic resonance (NMR) T₂ relaxation signals as a first portion of the input data measured in situ in the wellbore of the formation by an NMR tool.

6. The method of claim 5, wherein the one or more NMR T₂ relaxation signals comprise partially saturated signals in a time domain \tilde{M}(t) or in a T₂ domain \tilde{F}ₚ(T₂).

7. The method of claim 6, further comprising receiving a water saturation (S_{w}) value as a second portion of the input data measured in situ in the wellbore of the formation by the NMR tool.

8. The method of claim 7, further comprising receiving a bulk oil/hydrocarbon T₂ relaxation time distribution, G(T_{2,b,o}), as a third portion of the input data measured in situ in the wellbore of the formation by the NMR tool.

9. The method of claim 8, further comprising receiving a bulk water/brine T₂ relaxation time (T_{2,b,w}) as the auxiliary input data.

10. The method of claim 1, further comprising defining the T_{c} and the α as predetermined values or by correlation to mineralogy of the formation.

11. The method of claim 1, further comprising minimizing the difference between the modeled T₂ relaxation response and the measured T₂ relaxation response of the partially saturated formation in the time domain, in the T₂ domain, or in a singular value decomposition (SVD) compressed data domain.

12. The method of claim 1, further comprising generating the fully water saturated surface T₂ distribution as a single Gaussian distribution or as a summation of multiple Gaussian distributions in a logarithmic T₂ space.

13. A system comprising:
a nuclear magnetic resonance (NMR)-based logging tool configured to collect measured data in situ in a wellbore of a formation; and
a data processing system in communication with the NMR-based logging tool, wherein the data processing system is configured to perform operations comprising:
receiving one or more inputs, wherein the one or more inputs comprise:
one or more NMR transverse (T₂) relaxation signals as a first portion of the measured data as partially saturated signals in a time domain \tilde{M}(t) or in a T₂ domain \tilde{F}ₚ(T₂);
a water saturation (S_{w}) value as a second portion of the measured data;
a bulk oil/hydrocarbon T₂ relaxation time distribution, G(T_{2,b,o}), as a third portion of the measured data; and
a bulk water/brine T₂ relaxation time (T_{2,b,w}) as the auxiliary input data generated as lab data or based upon field data;
defining a characteristic time (T_{c}) and an exponent value (α) that controls a sharpness of a transition from first sized pores from first sized pores of the formation to second sized pores of the formation as model parameters;
generating a fully water saturated surface transverse (T₂) distribution utilizing the one or more inputs and the model parameters to realize a pore size distribution of the formation;
minimizing a difference between a modeled T₂ relaxation response of a partially saturated formation and a measured T₂ relaxation response of the partially saturated formation to obtain a wettability characteristic index of the formation;
constructing raw relative permeabilities for a pure water-wet formation scenario and a pure oil-wet formation scenario utilizing the pore size distribution of the formation as two end scenarios;
obtaining a relative permeability estimation utilizing the raw relative permeabilities and the wettability characteristic index of the formation to account for influence of wettability changes to the formation by performing interpolation between the two end scenarios; and
providing relative permeability estimation to a reservoir simulation model to characterize the formation.

14. The system of claim 13, wherein the data processing system is further configured to obtain the relative permeability estimation utilizing an irreducible water saturation (S_{w,i}) value of the formation and a residue oil fraction (Sₒᵣ) value of the formation, wherein the data processing system is further configured to determine the S_{w,i} value based on constriction of water flow with pure geometric origin.

15. The system of claim 13, wherein the data processing system is further configured to construct two pairs of raw relative permeabilities as the raw relative permeabilities.

16. The system of claim 13, wherein the data processing system is further configured to define the T_{c} and the α as predetermined values or by correlation to mineralogy of the formation.

17. The system of claim 13, wherein the data processing system is further configured to minimize the difference between the modeled T₂ relaxation response and the measured T₂ relaxation response of the partially saturated formation in the time domain, in the T₂ domain, or in a singular value decomposition (SVD) compressed data domain.

18. The system of claim 13, wherein the data processing system is further configured to generate the fully water saturated surface T₂ distribution as a single Gaussian distribution or as a summation of multiple Gaussian distributions in a logarithmic T₂ space.

19. A tangible, non-transitory, computer-readable medium comprising executable instructions that, when executed by processing circuitry, cause the processing circuitry to perform operations comprising:
receiving one or more inputs, wherein the one or more inputs comprise:
one or more nuclear magnetic resonance (NMR)-based logging tool measurement as measured data in situ in a wellbore of a formation, wherein the measured data comprises transverse (T₂) relaxation signals as a first portion of the measured data as partially saturated signals in a time domain [symbol] (t) or in a T₂ domain [symbol] (T₂), a water saturation (S_{w}) value as a second portion of the measured data, a bulk oil/hydrocarbon T₂ relaxation time distribution, G(T_{2,b,o}), as a third portion of the measured data, and a bulk water/brine T₂ relaxation time (T_{2,b,w}) as auxiliary input data generated as lab data or based upon field data;
defining a characteristic time (T_{c}) and an exponent value (α) that controls a sharpness of a transition from first sized pores of the formation to second sized pores of the formation as model parameters;
generating a fully water saturated surface transverse (T₂) distribution utilizing the one or more inputs and the model parameters to realize a pore size distribution of the formation;
minimizing a difference between a modeled T₂ relaxation response of a partially saturated formation and a measured T₂ relaxation response of the partially saturated formation to obtain a wettability characteristic index of the formation;
constructing raw relative permeabilities for a pure water-wet formation scenario and a pure oil-wet formation scenario utilizing the pore size distribution of the formation as two end scenarios;
obtaining a relative permeability estimation utilizing the raw relative permeabilities and the wettability characteristic index of the formation to account for influence of wettability changes to the formation by performing interpolation between the two end scenarios; and
providing relative permeability estimation to a reservoir simulation model to characterize the formation.

20. The tangible, non-transitory, computer-readable medium of claim 19, wherein the executable instructions, when executed by the processing circuitry, cause the processing circuitry to obtain the relative permeability estimation utilizing an irreducible water saturation (S_{w,i}) value of the formation and a residue oil fraction (Sₒᵣ) value of the formation, wherein the data processing system is further configured to determine the S_{w,i} value based on constriction of water flow with pure geometric origin.
